(19) United States
(12) Patent Application Publication
(10) Pub. No.: US 2006/0290425 A1
(43) Pub. Date: Dec. 28, 2006

(54) Isolated conversion apparatus for analog signal

(75) Inventor: Yu-Bin Chao, Taoyuan Hsien (TW)

Correspondence Address: HDSL, 4331 STEVENS BATTLE LANE, FAIRFAX, VA, 22033, US

(73) Assignee: Delta Electronics, Inc.

(21) Appl. No.: 11/159,182

(22) Filed: Jun. 23, 2005

(51) Int. Cl. H03F 3/217

(52) U.S. Cl. 330/251

(57) ABSTRACT

An isolated conversion apparatus for analog signal includes a filer, an amplification circuit, an isolation circuit, and a voltage follower. The amplifier includes a switch unit to select an input current signal or an input voltage signal. Alternatively, a large input current signal can be converted to a voltage signal by a precise resistor and the voltage signal is level-shifted by the amplifier. The shifted voltage signal is isolated from noise by the isolation circuit and output through the voltage follower. Therefore, the isolated conversion apparatus can provide analog signal conversion for voltage signal, current signal and large current signal, and isolation from ground.

### BACKGROUND OF THE INVENTION

1. Field of the Invention

The present invention relates to an isolated conversion apparatus for analog signal, especially to an isolated conversion apparatus for analog signal with independent input power source and isolated optical coupler, whereby the isolated conversion apparatus can be used in analog signal conversion for voltage signal, current signal and large current signal.

2. Description of Related Art

Analog to digital conversion is widely used in the signal control of electronic products. FIG. 1 shows a circuit diagram of a conventional analog to digital converter. The input signal may be voltage signal or current signal; and is proportionally amplified by an amplifier and then sent to a control end (such as a CPU). The input signal is generally limited to 0˜10V or 0˜20 mA. However, the voltage signal and the current signal should be separately input because input impedance difference. The analog to digital converter is generally limited to single signal operation mode, which is impractical.

The analog to digital converter for both voltage input signal and current input signal uses a selection switch and an amplification circuit with an OP amplifier (operational amplifier). The input impedance is selected according to input signal source. This can solve the problem of single signal operation mode. However, the feasible input current signal is still limited, for example, to several mA.

Moreover, the common ground design of conventional circuit will not provide isolation for a control end, such as CPU. The external noise will be coupled to the control end. The signal cannot be fetched for large current signal. The selection of resistor R4′ shown in FIG. 1 is difficult. Therefore, a conversion module, such as a current transformer, is needed to provide isolation for front stage and convert large signal to small signal. Alternatively, the current signal is converted to voltage signal by resistor to provide isolation effect. However, the complexity and the cost are increased for circuit design. The input terminal cannot be used both for current signal and voltage signal. Therefore, the input terminals should be separately provided and cannot be used both current signal and voltage signal.

### SUMMARY OF THE INVENTION

The present invention is intended to overcome the problem of conventional circuit. The present invention provides an independent input source and a simple selection switch. Moreover, a rear-stage optical coupler is used for providing isolation to overcome interference for analog signal. The present invention further provides applicability for large current signal and solves the problem of high-cost converter. Therefore, the circuit layout is simplified with compact size.

Accordingly, the present invention provides an isolated conversion apparatus comprising: a filter constituting a signal input with a voltage-dividing resistor; an amplification circuit for receiving an output from a filter and switching input voltage signal and input current signal with a switch unit to unify different signal source; an isolation circuit receiving the amplified signal and sending the amplified signal to a control end with the same phase.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a circuit diagram of a conventional analog to digital converter.

FIG. 2 shows a block diagram of a preferred embodiment of the present invention.

FIG. 3 shows a circuit diagram of a preferred embodiment of the present invention.

FIG. 4 shows a circuit diagram of another preferred embodiment of the present invention.

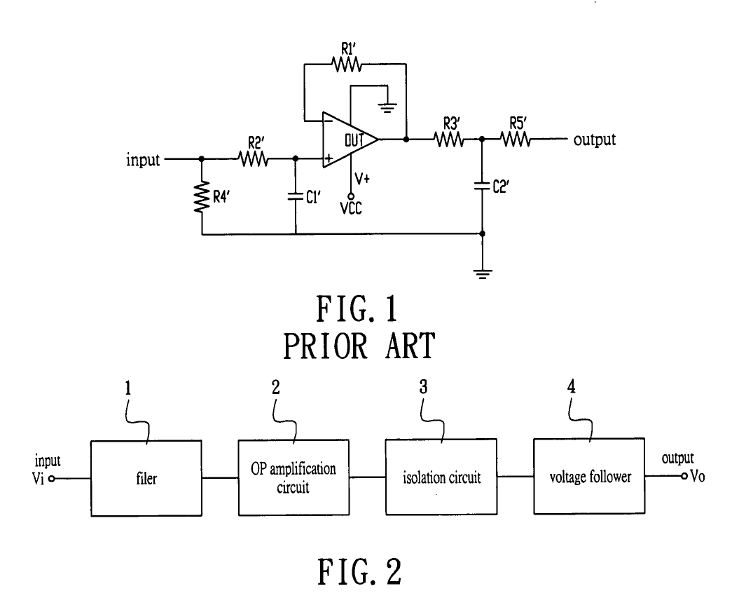

### DETAILED DESCRIPTION OF THE INVENTION

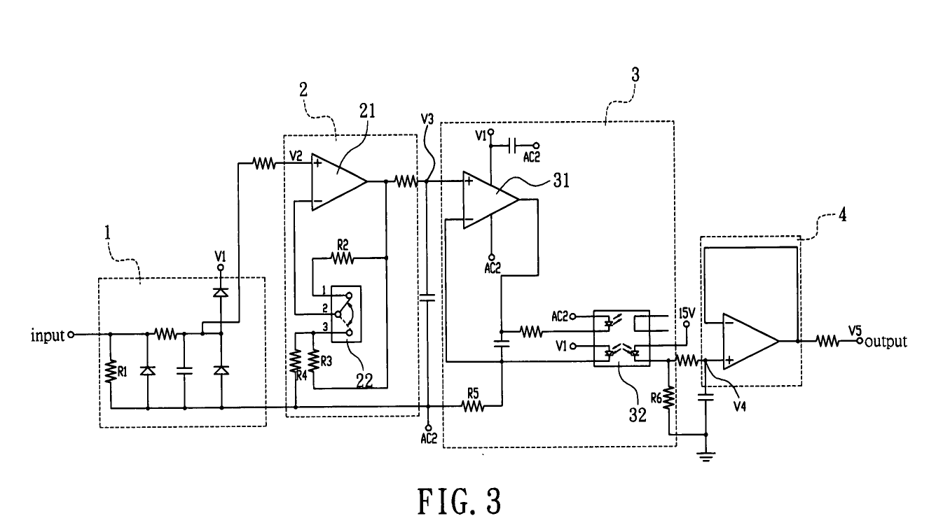

With reference now to FIGS. 2 and 3, the present invention discloses an isolated conversion apparatus for analog signal. The isolated conversion apparatus for analog signal comprises a filer 1, an amplification circuit 2, an isolation circuit 3, and a voltage follower 4. The isolated conversion apparatus can provide analog signal conversion for voltage signal, current signal and large current signal, and isolation from ground. Moreover, the isolated conversion apparatus has simple circuit layout with compact wiring design.

The filter 1 is connected to an input signal at an input end and used to reduce output ripples. The filter 1 comprises a current-dividing resistor R1, which is a precise high-power and low-resistance resistor. When the input signal has a large current, the current-dividing resistor R1 can bypass most of current from inputting to next stage. Therefore, the isolated conversion apparatus of the present invention can be used for application with several amperes in comparison with conventional range of several mA.

The amplification circuit 2 is connected to the output of the filter 1 and comprises an OP amplifier 21 and a switch unit 22 to output signal with common reference level. The OP amplifier 21 is connected to the filter 1 to receive an output signal V2. The switch unit 22 performs a switch operation for the resistors R2, R3 and R4 to generate signal matched with the input voltage or current signals. The amplification ratios for Switch nodes 1-2 and Switch nodes 2-3 are below:

Switch nodes 1-2 V2=V3

Switch nodes 2-3 V2=(1+R3/R4) V3

The isolation circuit 3 is connected to output of the amplification circuit 2 and comprises a comparator 31 and an optical coupler 32. The comparator 31 receives the common reference signal V3 of the amplification circuit 2 for analog signal processing. The processed signal is voltage divided by the optical coupler 32 with the resistors R5 and R6 to output a V4 signal as stated in formula below, thus achieving ground isolation for the input end and the output end.

$$V 4 = ( \frac{R 6}{R 5} ) V 3$$

The signal output by the isolation circuit 3 is sent to the non-inverting end of the voltage follower 4 and an output signal V5 is sent to the control end, in other word, V5=V4.

In above-mentioned circuit, the input end is isolated from the output end to minimize the interference from the output end. The provision of the optical coupler 32 with the resistors R5 and R6 also provides signal isolation effect and prevent interference of ground to a control end, such as CPU. Moreover, the control end can be protected even when the input end is short-circuited.

Moreover, the isolated conversion apparatus of the present invention also enhance the practicability by admitting both voltage and current input. The input port will not occupy additional space and the circuit layout can be simplified.

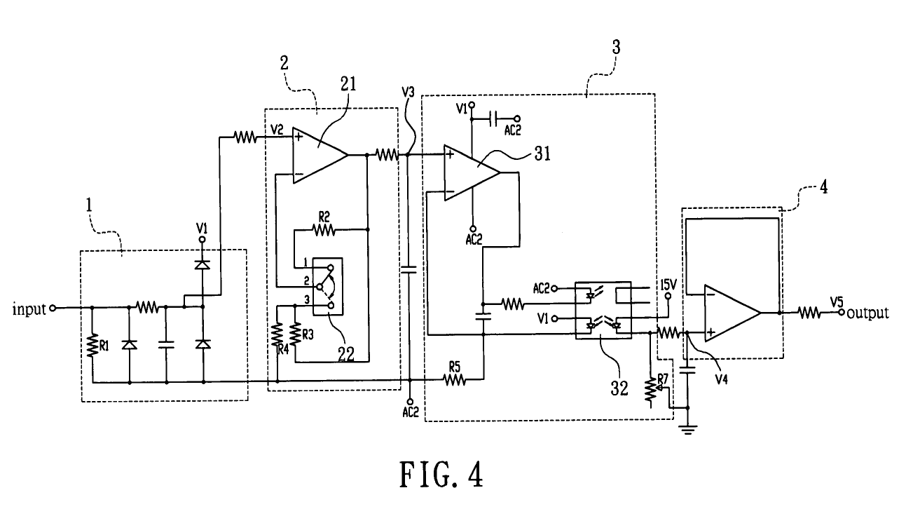

FIG. 4 shows the isolated conversion apparatus according to another preferred embodiment. This preferred embodiment is similar to that shown in FIGS. 2 and 3 except that the resistor R6 in the isolation circuit 3 is replaced by a variable resistor R7 for tuning an optimal resistance for voltage division with the resistor R5. Therefore, the isolation circuit 3 can effectively isolate noise from bothering the control end.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. An isolated conversion apparatus used for isolating a signal source from ground, the isolated conversion apparatus comprising
an amplification circuit for receiving an output from a filter and generating a common reference amplified signal; and
an isolation circuit receiving the amplified signal and isolating noise from the amplified signal.

2. The isolated conversion apparatus as in claim 1, wherein the amplification circuit comprises an OP amplifier (operational amplifier), a switch unit and a plurality of resistors.

3. The isolated conversion apparatus as in claim 1, wherein the isolation circuit comprises a comparator and an optical coupler.

4. The isolated conversion apparatus as in claim 1, further comprising a first resistor connected to an input of the optical coupler and a second resistor connected to an output of the optical coupler to form a voltage divider.

5. The isolated conversion apparatus as in claim 4, wherein the second resistor is a variable resistor.

6. The isolated conversion apparatus as in claim 1, further comprising a filter connected to an input of the amplification circuit.

7. The isolated conversion apparatus as in claim 6, wherein the filter comprises a current-dividing resistor, which is a precise high-power and low-resistance resistor.

8. The isolated conversion apparatus as in claim 1, further comprising a voltage follower connected to an output end of the isolated conversion apparatus.

9. The isolated conversion apparatus as in claim 8, wherein the voltage follower is an OP amplifier (operational amplifier).

10. The isolated conversion apparatus as in claim 1, wherein the signal source is a voltage signal source, a current signal source or a large current signal source.
